(19) United States
(12) Patent Application Publication
(10) Pub. No.: US 2012/0314175 A1
(43) Pub. Date: Dec. 13, 2012

(54) COF, COF CARRIER TAPE AND DRIVE CIRCUIT OF LIQUID CRYSTAL TELEVISION

(75) Inventors: Po-shen Lin, Shenzhen (CN); Liang-chan Liao, Shenzhen (CN); Yong Zhang, Shenzhen (CN)

(73) Assignee: SHENZHEN CHINA STAR OPLOELECTRONICS TECHNOLOGY CO., LTD., Shenzhen, Guangdong (CN)

(21) Appl. No.: 13/380,045

(22) PCT Filed: Jul. 26, 2011
(86) PCT No.: PCT/CN2011/077594

§ 371 Date: Dec. 22, 2011

(30) Foreign Application Priority Data
Jun. 9, 2011 (CN) 201110152666.5
Jul. 26, 2011 (CN) PCT/CN2011/077594

(51) Int. Cl. G02F 1/1345; H05K 7/00

(52) U.S. Cl. 349/149; 361/783

(57) ABSTRACT

A COF tape is formed by orderly connecting several COFs and a carrier connected with said COF tape. The appearance of said COF is a trapezoid consisting of two paralleled wiring edges and two unparalleled side edges. The longer wiring edge of one COF and the shorter wiring edge of the other COF between the two adjacent COFs are connected and lie in a same straight line; the shorter wiring edges and the longer wiring edges of the other two COFs also lie in a same straight line. The disclosure also discloses a COF and a drive circuit for liquid crystal display television. The COF of the disclosure saves materials; the carrier-tape type semiconductor device with the COF of the disclosure is able to increase the quantity of COF on the carrier tape of specific length, so that the cost can be lowered to a large extent.

### BACKGROUND

1. Technical Field

The disclosure relates to a COF (Chip On Film), specifically to a COF, COF carrier tape and a drive circuit of liquid crystal television.

2. Description of Related Art COF carrier tape joints the semiconductor elements and then installs them on the long carrier tape. COF uses a soft additional circuit board as the packaged chip carrier in order to joint the chip and the soft substrate circuits; or COF only refers to the soft additional circuit board of the unpackaged chip. As is shown in FIG. 1, COF is formed by jointing the chip (such as source driver IC or gate driver IC, etc. see the black-coloured shadow part in FIG. 1) and installing the chip on a flexible wiring substrate on which the wiring diagrams are formed. The wiring diagrams of COF are generally composed of an internal lead connected with the chip electrode and an external lead connected with the external circuit. Generally, in the driver circuit of the liquid crystal display television, the wiring on one end of COF connected to the PCB (Printed Circuit Board) is sparse, while the wiring on the other end connected to the panel is dense. FIG. 1 shows one type of the existing COF, wherein the wiring number of one wiring edge are sparse but occupies the same side length as the other wiring edge. COF is a rectangular structure, which wastes unnecessary COF area and increases the material cost. FIG. 2 is the schematic diagram showing the structure of existing COF carrier tape. The COF 100 in the COF carrier tape is a rectangular structure; the area of shadow part 101 is useless, however, it still occupies partial area of the carrier tape and will waste massive material in the process of production.

### SUMMARY

The main purpose of the disclosure is to provide a COF, a COF carrier tape and a drive circuit of the liquid crystal display television, which aims at saving COF area, improving the utilization ratio of the carrier tape and effectively lowering the production cost.

The disclosure discloses a COF carrier tape, including a COF tape formed by orderly connecting several COFs and a carrier connected with said COF tape; the appearance of said COF is a trapezoid consisting of two paralleled wiring edges and two unparalleled side edges; the longer wiring edge of one COF and the shorter wiring edge of the other COF between the two adjacent COFs are connected and lie in a same straight line; other shorter wiring edges and the longer wiring edges of the two COFs also lie in a same straight line.

Preferably, said carrier includes two paralleled long edges, and the two wiring edges of said COF are all in parallel with said long edges.

Preferably, said COF is a right trapezoid structure or an isosceles trapezoid structure; the two wiring edges respectively refer to the upper bottom edge and the lower bottom edge of the trapezoid.

Preferably, each said COF has same size and same area. Preferably, the edge of the long side of said carrier is respectively provided with a plurality of through holes.

The disclosure further discloses a COF, which appearance is a trapezoid consisting of two paralleled wiring edges and two unparalleled side edges.

Preferably, said COF is a right trapezoid structure or an isosceles trapezoid structure; the two wiring edges respectively refer to the upper bottom edge and the lower bottom edge of the trapezoid.

Preferably, said COF includes strip-shaped semiconductor components; and said strip-shaped semiconductor components are vertical to the wiring edges of said COF.

Preferably, said COF includes strip-shaped semiconductor components; and said strip-shaped semiconductor components are in parallel with the wiring edges of said COF.

Preferably, one wiring edge of said COF is provided with a plurality of connecting wires capable of being connected with the external PCB, and the other wiring edge is provided with a plurality of connecting wires capable of being with the external panel.

The disclosure further discloses a drive circuit for the liquid crystal display television, including a COF, wherein one of the wiring edges of said COF is connected with the PCB and the other one is connected with the external panel; the appearance of said COF is a trapezoid consisting of two paralleled wiring edges and two unparalleled side edges.

Preferably, said COF is a right trapezoid structure or an isosceles trapezoid structure; the two wiring edges respectively refer to the upper bottom edge and the lower bottom edge of the trapezoid.

Preferably, said COF includes strip-shaped semiconductor components; and said strip-shaped semiconductor components are vertical to the wiring edges of said COF.

Preferably, said COF includes strip-shaped semiconductor components; and said strip-shaped semiconductor components are in parallel with the wiring edges of said COF.

The COF of the disclosure is a quadrilateral structure with two wiring edges mutually paralleled, meanwhile, the lengths of the two wiring edges are different; for examples, the COF is a trapezoid, a right trapezoid or an isosceles trapezoid. Such shaped COF can be suitable for the ones with sparse wiring quantity on one wiring edge and with dense wiring quantity on the other wiring edge. The trapezoid-structured COF saves more materials and reduces more costs compared with the rectangle-structured COF. COF carrier tape includes a COF tape formed by orderly connecting several COFs and a carrier connected with said COF tape. The appearance of said COF is a trapezoid consisting of two paralleled wiring edges and two unparalleled side edges. The longer wiring edge of one COF and the shorter wiring edge of the other COF between two adjacent COFs are connected and lie in a same straight line, the shorter wiring edges and the longer wiring edges of the other two COFs also lie in a same straight line. Specifically, the adjacent COFs are arranged on the COF carrier tape by rotating relatively 180-degree, the same-shaped COF can be obtained by punching from the COF carrier tape. Therefore, in the carrier-tape type semiconductor device with the COF of the disclosure is able to increase the quantity of COF on the carrier tape of specific length, so that the cost can be lowered to a large extent.

### DESCRIPTION OF THE DRAWINGS

FIG. 1 is the schematic diagram showing the structure of the existing COF connected with the external;

FIG. 2 is the schematic diagram showing the structure of the existing COF carrier tape;

FIG. 3 is the schematic diagram showing the structure of the COF in the first embodiment according to the disclosure;

FIG. 4 is the schematic diagram showing the structure of the COF carrier tape in the first embodiment according to the disclosure;

FIG. 5 is the schematic diagram showing the structure of the COF in the second embodiment according to the disclosure;

FIG. 6 is the schematic diagram showing the structure of the COF carrier tape in the second embodiment according to the disclosure;

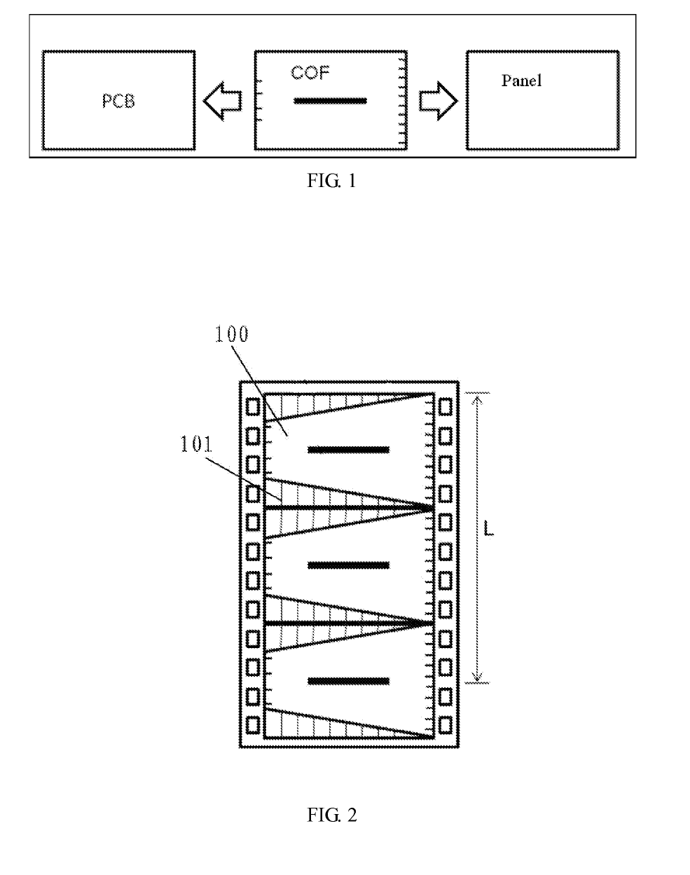

The purpose implementation, the function features and advantages of the disclosure will be further illustrated by integrating the exemplary embodiments and taking the attached drawings as references.

### DETAILED DESCRIPTION

It should be understood that the described exemplary embodiment is only used for illustrating this disclosure rather than limiting.

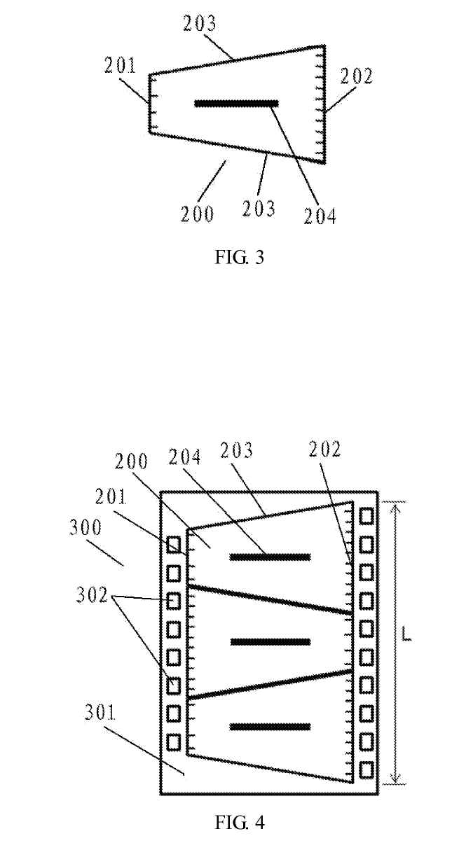

Take FIG. 3 as a reference, which is the schematic diagram showing the structure of the COF 200 in a first embodiment according to the disclosure. The appearance of COF 200 is shaped as a trapezoid formed with two opposite paralleled wiring edges and two unparalleled side edges 203 connected therebetween. The COF 200 in this embodiment is an isosceles trapezoid structure, the two wiring edges of which respectively refer to the upper bottom side 201 and the lower bottom side 202 of the trapezoid. One short wiring edge (upper bottom side 201) of the COF 200 is provided with a plurality of connecting wires capable of being connected with the external PCB, and the other long wiring edge (lower bottom side 202) is provided with a plurality of connecting wires capable of being connected with the external panel. The wirings arranged on the upper bottom side 201 are sparse, while the wirings arranged on the lower bottom side 202 are dense. The upper bottom side and the lower bottom side of the COF in this embodiment are provided with four and ten wirings, respectively; or the quantity can be various. Said COF 200 includes strip-shaped semiconductor components 204 or IC chips; said strip-shaped semiconductor components 204 are arranged vertical to the wiring edges of COF 200, or the strip-shaped semiconductor components are arranged in parallel with any one wiring edge of the COF. Said strip-shaped semiconductor components 204 can be further arranged on other parts of the COF 200, and the position of which are determined according to the practical requirement.

The appearance of COF 200 of the disclosure is an isosceles trapezoid. The COF 200 of such shape is suitable for the one with sparse wiring quantity on one wiring edge (upper bottom side 201) and with dense wiring quantity on the other wiring edge (lower bottom side 202), which can save the wiring-free parts. The trapezoid-structured COF 200 saves more materials and reduces more costs compared with the rectangle-structured COF 200.

Take FIG. 4 as a reference, which is the schematic diagram showing the structure of the COF carrier tape 300 in the first embodiment according to the disclosure. Such COF carrier tape 300 includes a COF tape formed by orderly connecting several COFs 200 and a carrier 301 connected with said COF tape. The COF 200 is a trapezoid consisting of two paralleled wiring edges and two unparalleled side edges 203, the longer wiring edge 202 of one COF 200 and the shorter wiring edge 201 of the other COF 200 between the two adjacent COFs 200 are connected and lie in a same straight line, the shorter wiring edges 201 and the longer wiring edges 202 of the other two COFs 200 also lie in a same straight line. Specifically, the adjacent COFs 200 are arranged on the COF carrier tape 300 by rotating relatively 180-degree. Each COF 200 on the COF carrier tape 300 is same in size and area. COF 200 is a trapezoid structure, and the COF 200 in this embodiment is an isosceles trapezoid the two wiring edges of which respectively refer to the upper bottom edge 201 and the lower bottom edge 202 of the trapezoid. One oblique waist edge 203 of one COF 200 is jointed and close to the oblique waist edge 200 of the other COF 200. The carrier 301 includes two paralleled long sides, and both the two wiring edges of COF 200 are in parallel with the carrier 301 and the long edges. The edge of the long side on the carrier 301 is respectively provided with a plurality of through holes 302, which are convenient for the COF carrier tape 300 to be connected with the external cutting equipment. The through holes 302 drive the COF carrier tape 300 to move accurately and incise each COF 200 completely with fine accuracy. The upper bottom edge 201 of the COF 200 of the isosceles trapezoid in this embodiment corresponds to two through holes 302, and the lower bottom edge 202 corresponds to four through holes 302. The COF 200 includes strip-shaped semiconductor components 204. According to the practical requirement, the strip-shaped semiconductor components 204 can be arranged on any position of the COF 200. The strip-shaped semiconductor components 204 in this embodiment are vertical to the wiring edges of COF 200.

As is shown is FIG. 2, in the COF carrier tape of prior art, the COF carrier tape with the length of L obtains 2.5 COF; while the COF carrier tape fully makes use of the needless area (the area of the shadow part 101 in FIG. 2). Therefore, 10/3 quantity of COF can be obtained on the COF carrier tape with length of L; as a result, compared with the rectangle-structured COF 200, the disclosure can save 25% of carrier tapes and improve the utilization efficiency of carrier tapes in order to obtain COF 200 of same quantity. Therefore, the cost of the COF 200 can greatly reduced in the aspect of the production price.

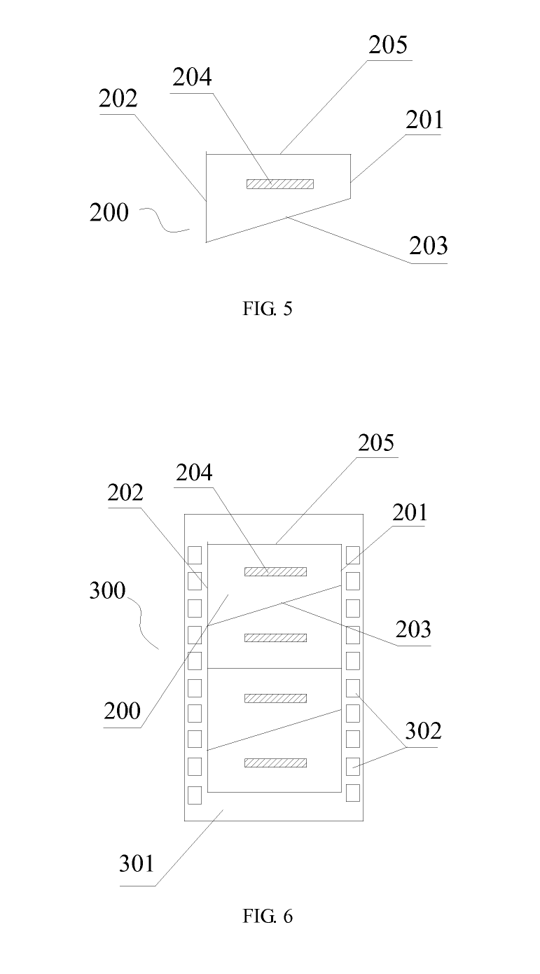

Take FIG. 5 as a reference, which the schematic diagram showing the structure of the COF in the second embodiment according to the disclosure. The difference between this embodiment and said COF 200 of the first embodiment lies in that the shape of the COF 200 is different. The COF 200 of the second embodiment is right-trapezoid shaped, the two wiring edges of which respectively refer to the upper bottom side 201 and the lower bottom side 202; the upper bottom side 201 of the COF 200 is provided with a plurality of connecting wires capable of being connected with the external PCB, and the lower bottom side 202 is provided with a plurality of connecting wires capable of being connected with the external panel. The wirings arranged on the upper bottom side 201 are sparse, while the wirings arranged on the lower bottom side 202 are dense. Besides, a right-angle side 205 and an oblique waist side 203 are provided. Compared with the rectangle-structured COF 200, the right-trapezoid structured COF 200 also saves the materials and reduces the cost.

Take FIG. 6 as a reference, which is the schematic diagram showing the structure of the

COF carrier tape 300 in the second embodiment according to the disclosure. The COF carrier tape 300 of this embodiment adopts the second embodiment of said COF 200. The difference between this embodiment and the first embodiment of the carrier tape 300 lies in that the COF 200 of this embodiment is right-trapezoid structured. The lower bottom side 202 of one COF 200 and the upper bottom side 201 of the other COF 200 between the two adjacent COFs 200 are connected and lie in a same straight line; the upper bottom side 201 and the lower bottom side 202 of the other two COFs 200 are also connected and lie in a same straight line. Specifically, the adjacent COFs 200 are arranged on the COF carrier tape 300 by rotating relatively 180-degree. The bevel edges of the right trapezoids between the two adjacent COFs 200 are closely connected, the right-angle sides 205 are closely connected with the right-angle sides 205 of the other COF 200. Each COF 200 on the COF carrier tape 300 has same shape and area. The COF carrier tape 300 of this embodiment also saves the materials of the carrier tape, improves the utilization ratio and greatly reduces the cost.

The manufacturing method of COF carrier tape 300 lies as follows. When the COF 200 is designed on the carrier 301, the COF 200 is designed into a trapezoid, a right trapezoid or an isosceles trapezoid according to the practical application; the wiring edge of the COF 200 is determined according to the practical requirement, the wiring quantity and the wiring interval.

The disclosure further discloses a drive circuit of the liquid crystal display television, including at least one COF 200 (see FIG. 3 and FIG. 5 as references). One wiring edge of COF 200 is connected with PCB, and the other wiring edge can be connected with the external panel; the outer appearance of COF 200 is a trapezoid consisting of two paralleled wiring edges and two unparalleled side edges. The structure of the COF 200 is a right trapezoid or an isosceles trapezoid. Said two wiring edges separately refer to the upper bottom side 201 and the lower bottom side 202. The COF 200 with isosceles-trapezoid structure is a preferable method. COF 200 includes strip-shaped semiconductor components 204, which are vertical to the wiring edges of COF 200. Or, such strip-shaped semiconductor components 204 are in parallel with the wiring edges of COF 200. The COF 200 of the drive circuit for the liquid crystal display in this embodiment television includes all technical methods mentioned by the first embodiment and the second embodiment of COF 200; meanwhile, the reached technical effects are same, thus details would not be illustrated here.

What is illustrated above is just a preferable exemplary embodiment, which will not limit the patent scope of the disclosure. Any equivalent replacements made by the specifications and drawings of the disclosure, which are directly or indirectly applied to other technical fields, should be included into the protection scope of the disclosure.

What is claimed is:

1. A COF carrier tape comprising a COF tape formed by orderly connecting several COF and a carrier connected with said COF tape; the appearance of said COF is a trapezoid consisting of two paralleled wiring edges and two unparalleled side edges; the longer wiring edge of one COF and the shorter wiring edge of the other COF between said two adjacent COFs are connected and lie in a same straight line; the shorter wiring edges and the longer wiring edges of the other two COFs also lie in a same straight line.

2. The COF carrier tape of claim 1, wherein the COF is a right trapezoid structure or an isosceles trapezoid structure; the two wiring edges respectively refer to the upper bottom edge and the lower bottom edge of the trapezoid.

3. The COF carrier tape of claim 2, wherein the carrier comprises two paralleled long edges, and the two wiring edges of said COF are all in parallel with said long edges.

4. The COF carrier tape of claim 1, wherein each the COF has same size and same area.

5. The COF carrier tape of claim 3, wherein the COF has same size and same area.

6. The COF carrier tape of claim 5, wherein the edge of the long side of said carrier is respectively provided with a plurality of through holes.

7. A COF, wherein the appearance of said COF is a trapezoid consisting of two paralleled wiring edges and two unparalleled side edges.

8. The COF of claim 7, wherein the COF is a right trapezoid structure or an isosceles trapezoid structure; the two wiring edges respectively refer to the upper bottom edge and the lower bottom edge of the trapezoid.

9. The COF of claim 8, wherein the COF comprises strip-shaped semiconductor components; and said strip-shaped semiconductor components are vertical to the wiring edges of said COF.

10. The COF of claim 7, wherein the COF comprises strip-shaped semiconductor components; and said strip-shaped semiconductor components are in parallel with the wiring edges of said COF.

11. The COF of claim 9, wherein one wiring edge of the COF is provided with a plurality of connecting wires capable of being connected with the external PCB, and the other wiring edge is provided with a plurality of connecting wires capable of being with the external panel.

12. A drive circuit for the liquid crystal display television, comprising a COF, wherein one of the wiring edges of said COF is connected with the PCB and the other one is connected with the external panel; the appearance of said COF is a trapezoid consisting of two paralleled wiring edges and two unparalleled side edges.

13. The drive circuit for the liquid crystal display television of claim 12, wherein the COF is a right trapezoid structure or an isosceles trapezoid structure; the two wiring edges respectively refer to the upper bottom edge and the lower bottom edge of the trapezoid.

14. The drive circuit for the liquid crystal display television of claim 13, wherein the COF comprises strip-shaped semiconductor components; and said strip-shaped semiconductor components are vertical to the wiring edges of said COF.

15. The drive circuit for the liquid crystal display television of claim 13, wherein the COF comprises strip-shaped semiconductor components; and said strip-shaped semiconductor components are in parallel with the wiring edges of said COF.
